(19) United States
(12) Patent Application Publication
(10) Pub. No.: US 2026/0342110 A1
(43) Pub. Date: Oct. 29, 2026

(54) BATTERY MONITORING AND PROTECTION MODULE AND BATTERY MANAGEMENT SYSTEM FORMED BY USING THE SAME

(71) Applicant: ETI CA BATTERY INC., New Taipei City (TW)

(72) Inventor: Wei-Chen WU, New Taipei City (TW)

(73) Assignee: ETI CA BATTERY INC., New Taipei City (TW)

(21) Appl. No.: 19/241,884

(22) Filed: Jun. 18, 2025

(30) Foreign Application Priority Data
Apr. 25, 2025 (TW) 114115657

(51) Int. Cl. H02J 7/60; G01R 31/374; G01R 31/3842; H01M 10/42; H02J 7/40

(52) U.S. Cl. CPC H02J 7/60; G01R 31/374; G01R 31/3842; H01M 10/425; H02J 7/40; H01M 2010/4271

(57) ABSTRACT

A battery monitoring and protection module and a battery management system formed by using the same are provided and applicable to monitoring and protecting a status of at least one battery. The disclosed module includes a battery monitor and control circuit, a first stage notification switch and a second stage notification switch. When the battery is approaching abnormal, a battery detecting and managing circuit controls the first stage notification switch to form an open circuit, and disables a power conditioning device to pause and observe the battery first. On the other hand, when the battery is abnormal, both the first and second stage notification switches are open, and the battery detecting and managing circuit disconnects a battery protection switch to cut current and protect batteries. By employing the present invention, it is believed that less communication rate for data transmission is achieved, so that power consumption can be reduced.

### BACKGROUND OF THE INVENTION

This application claims priority for the TW Application No. 114115657 filed on 25 Apr. 2025, the content of which is incorporated by reference in its entirely.

### Field of the Invention

The present invention relates to a battery management technology for high voltage batteries. More particularly, the present invention is related to a management method for high voltage batteries, in which a variety of notification switches are adopted so that the battery status signals can be transmitted at a lower communication rate for reducing the power consumption. In addition, no malfunction will be generated as well.

### Description of the Prior Art

As known, an overall voltage of the existing energy storage batteries is mostly controlled at voltages greater than 300 volts (V) for the purpose of accompanying used in a power conversion system (PCS). And therefore, a DC high-voltage power supply system has been acknowledged.

In view of the assembly of such DC high-voltage power supply system, it generally comprises a plurality of modules having lower voltages (for instance, 50V battery module is provided first) and by cascading these battery modules having lower voltages, a high-voltage battery system can be formed. For example, a 300V high-voltage battery system can be formed by cascading six 50V battery modules.

However, it has been known that for the current existing lithium batteries, a protection switch is usually necessary, such that when there is abnormality occurred in the battery, the protection switch can be disconnected in order to protect the battery. On account of this, an overall protection switch together with a management system are mostly provided with the above-mentioned series-connected battery modules, such that when any one battery of the series-connected battery modules has an abnormality, the management system is able to activate the protection switch promptly, so as to cut off the current and protect the battery module.

Please refer to FIG. 1, which schematically shows a structural diagram of a basic structure of a conventional battery module in the prior art. As illustrated in FIG. 1, a low voltage battery module includes a plurality of battery cells 11, wherein each battery cell 11 is electrically coupled to a battery monitoring circuit 12. The battery monitoring circuit 12 has a communication signal isolation interface 13, such that by employing such communication signal isolation interface 13, the battery status can be reported to a battery management system through the communication signal isolation interface 13. The whole system can be referred to FIG. 2, in which FIG. 2 schematically shows a structural diagram of a high voltage battery system formed by using the battery module in FIG. 1. As illustrated in FIG. 2, a plurality of low voltage battery modules of FIG. 1 are serially connected and each is electrically connected with a protection switch unit 22. And, the battery status of each low voltage battery module can be reported to the battery management system 24 through the communication signal isolation interface 13. As such, when any battery cell 11 has abnormality, the battery management system 24 is able to receive the communication signal and control the protection switch unit 22 to be disconnected, such that current is cut and battery can be under well protection.

However, it is worth noting that in order to achieve a prompt and instant protection, an extremely rapid communication rate is usually required so as to monitor each battery module. Under such a circumstance, a huge power consumption waste has generally occurred. Meanwhile, the accuracy of the communication data also needs to be confirmed at any time, resulting in a very high complexity in the procedure of processing communication data in the existing technology. In addition, since communication data also requires adequate processing time, when a certain low-voltage battery module in the entire system may have an abnormality, and yet the communication is still processing under other battery modules, in-time protection will be delayed and can not be activated immediately. Therefore, on account of the above mentioned descriptions, it is obvious that when the communication mode of the existing technology is used in the prior arts, not only power consumption but also system complexity will be significantly increased. Apart from these deficiencies, the protection cannot be activated immediately as well. So far, these have been known as several shortcomings and defects of the existing technology that need to be improved in the technical fields.

Therefore, on account of above, to overcome the above-mentioned problems, it should be obvious that there is indeed an urgent need for the professionals in the field for proposing a new battery monitoring and protection module and battery management system formed by using the same, which are to be developed that can effectively solve the above-mentioned problems occurring in the prior design. And by using such technical contents of the present invention, not only the current communication data modes are improved. An even faster and more instant battery protection can be achieved in time. Meanwhile, a lower communication rate for reducing the power consumption and no malfunction of the battery system can be ensured. As a result, by providing the present invention, it is believed that those long-standing shortcomings in the prior arts can be successfully solved. Hereinafter, the detailed specific implementations will be fully described in the following paragraphs.

### SUMMARY OF THE INVENTION

In order to overcome the above-mentioned disadvantages, one major objective in accordance with the present invention is to provide a battery monitoring and protection module, which is applicable to monitoring and protecting a status of at least one battery. The present invention is effective in improving the conventional communication mode of the prior art and proposes a more efficient battery protection management technology, which can be used to protect the at least one battery in time.

In addition, another objective of the present invention is to provide a battery management system formed by using the battery monitoring and protection module. By connecting a plurality of the battery monitoring and protection modules in series with a battery detecting and managing circuit, the present invention is able to disable a power conditioning device to pause and observe the battery when the battery is approaching abnormal. And subsequently, if the battery is abnormal, at least one battery protection switch is adopted to form an open circuit, such that a current flowing through the battery is cut in order to stop and protect the battery.

As a result, to sum above, the present invention is aimed to disclose a management method for high voltage batteries system. In related to the management method for protecting the batteries, a lower signal communication rate is achieved for significantly reducing the enormous power consumption generated in the prior arts. In addition, no malfunction of the system will be generated as well.

For achieving the above mentioned objectives, the technical solutions of the present invention are aimed to provide a battery monitoring and protection module first. The proposed battery monitoring and protection module is provided to monitor and protect a status of at least one battery, and the proposed battery monitoring and protection module comprises a battery monitor and control circuit, a first stage notification switch and a second stage notification switch. According to the embodiment of the present invention, the at least one battery is electrically coupled to an input terminal of the battery monitor and control circuit. The first stage notification switch is electrically coupled to a first output terminal of the battery monitor and control circuit, and the second stage notification switch is electrically coupled to a second output terminal of the battery monitor and control circuit. The battery monitor and control circuit is operable to detect the status of the at least one battery and accordingly controls the first stage notification switch and the second stage notification switch so as to protect the at least one battery.

In one embodiment of the present invention, when the battery monitor and control circuit detects the status of the at least one battery is normal, each of the first stage notification switch and the second stage notification switch forms a short circuit.

In another embodiment of the present invention, when the battery monitor and control circuit detects the status of the at least one battery is approaching abnormal, then the battery monitor and control circuit controls the first stage notification switch to form an open circuit, and the second stage notification switch to form a short circuit.

And yet, in one another embodiment of the present invention, when the battery monitor and control circuit detects the status of the at least one battery is abnormal, then the battery monitor and control circuit controls each of the first stage notification switch and the second stage notification switch to form an open circuit.

According to the technical contents of the present invention, the above mentioned status of the at least one battery includes: a normal status, an abnormal status and an approaching-abnormal status of the at least one battery regarding an operating voltage, an operating current and an operating temperature of the at least one battery.

Apart from the above, it is believed that each of the first stage notification switch and the second stage notification switch can be implemented by using a relay or an optical coupler switch.

In addition, a first isolation driving signal is provided between the battery monitor and control circuit and the first stage notification switch, such that the battery monitor and control circuit uses the first isolation driving signal for controlling the first stage notification switch. A second isolation driving signal is provided between the battery monitor and control circuit and the second stage notification switch, such that the battery monitor and control circuit uses the second isolation driving signal for controlling the second stage notification switch. In addition, the battery monitor and control circuit further comprises a third output terminal which is electrically coupled to an external isolated communication interface, and the external isolated communication interface is different from communication interfaces coupled to the above mentioned first stage notification switch and to the above mentioned second stage notification switch.

And therefore, by adopting the proposed circuit configurations of the present invention, when there are a plurality of batteries which are connected in series in a system, and the serially connected batteries are commonly coupled to the disclosed battery monitor and control circuit, the battery monitor and control circuit is operable to protect the at least one battery by controlling the first stage notification switch and the second stage notification when the status of any one battery is changed.

In another aspect, the present invention also provides a battery management system formed by using the above mentioned battery monitoring and protection module. The disclosed battery management system includes a plurality of the previously proposed battery monitoring and protection modules which are connected in series, a battery detecting and managing circuit which is electrically connected to the first stage notification switch of each of the battery monitoring and protection modules, and a power conditioning device. According to the embodiment of the present invention, the power conditioning device is electrically connected to the battery detecting and managing circuit, and therefore, when the battery detecting and managing circuit detects the first stage notification switch of any of the battery monitoring and protection modules forms an open circuit, the battery detecting and managing circuit is operable to disable the power conditioning device so as to pause and observe the at least one battery.

In such an embodiment, the first stage notification switch of each of the battery monitoring and protection modules is serially connected.

Moreover, the battery detecting and managing circuit can be further electrically connected to the second stage notification switch of each of the battery monitoring and protection modules, and the second stage notification switch of each of the battery monitoring and protection modules is serially connected. As such, when the battery detecting and managing circuit detects the second stage notification switch of any of the battery monitoring and protection modules forms the open circuit, the battery detecting and managing circuit is operable to control at least one battery protection switch disposed therein the system to be open so as to cut a current flowing through the at least one battery in order to stop and protect the at least one battery.

According to one feasible embodiment of the present invention, the disclosed battery detecting and managing circuit may alternatively further comprise a micro processor, such that the battery detecting and managing circuit uses the micro processor to disable the power conditioning device so as to pause and observe the at least one battery. In such an embodiment, an RS485 communication interface or an ethernet interface can be provided between the micro processor and the power conditioning device, such that the micro processor is operable to control the power conditioning device via the RS485 communication interface or the ethernet interface.

Alternatively, according to another feasible embodiment of the present invention, then the disclosed power conditioning device may further comprise an emergency stop, such that the battery detecting and managing circuit disables the power conditioning device by activating the emergency stop. As such, it is believed that both the foregoing embodiments can be implemented for achieving the purposes of the invention regarding battery protection.

As a result, to sum up, it is obvious that by employing the disclosed battery monitoring and protection module as well as the battery management system formed by using the same, not only a lower communication rate can be used for signal transmission in the system in order to reduce power consumption, but also an accurate data transmission result can be guaranteed. And therefore, as compared to the prior arts, it is believed that the present invention is characterized by a merit of novelty and inventive benefits.

It is worth emphasizing that, the embodiments disclosed in the present invention are merely described as taking a conventional battery as an illustrative exemplary example. The purpose is to enable those skilled in the art to fully understand the technical spirits of the present invention, but not intend to limit the application of the present invention. In other words, the disclosed technical contents as provided in the present invention can be applied not only to conventional batteries, but also to various battery types, such as lithium batteries as well. The present invention is certainly not limited thereto the batteries types.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 schematically shows a structural diagram of a basic structure of a conventional battery module in the prior art.

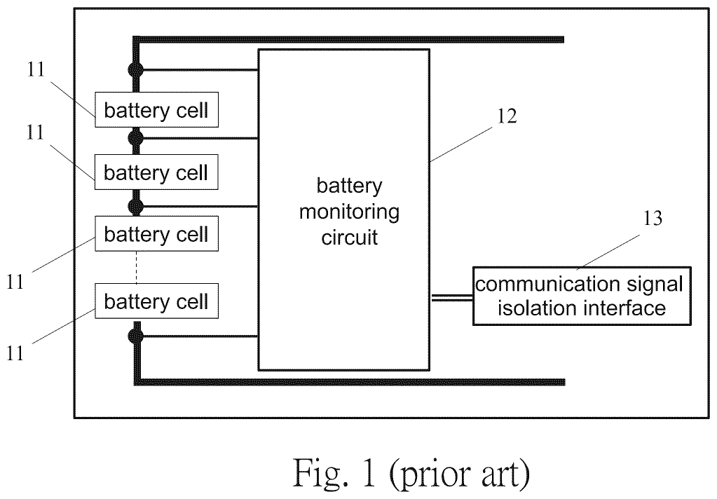

FIG. 2 schematically shows a structural diagram of a high voltage battery system formed by using the battery module in FIG. 1.

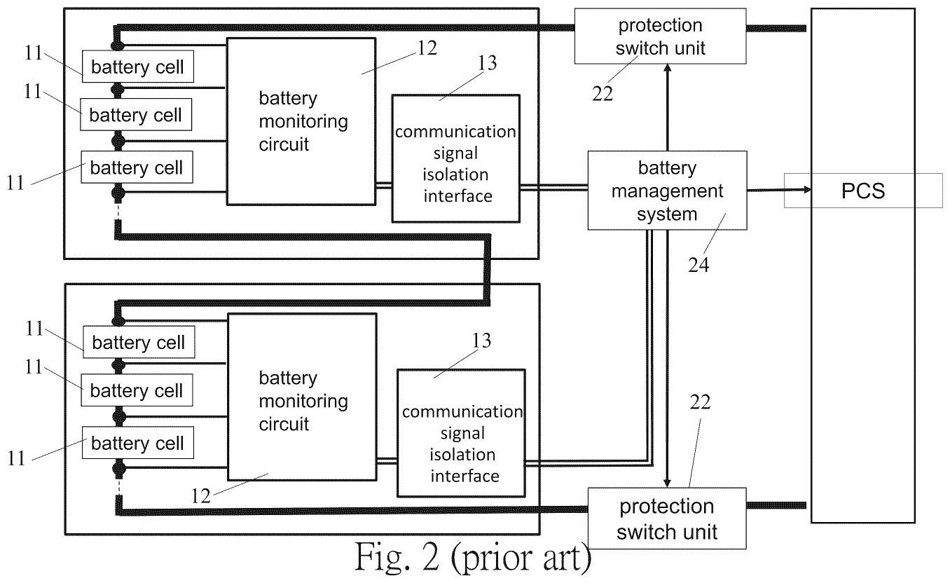

FIG. 3 shows a structural diagram schematically illustrating a battery monitoring and protection module in accordance with one embodiment of the present invention.

FIG. 4 shows a structural diagram schematically illustrating a battery management system formed by using the above mentioned battery monitoring and protection module in accordance with the embodiment of the present invention.

FIG. 5 schematically shows an indicative diagram illustrating the signal transmission process according to the embodiment in FIG. 4, when a first stage abnormality occurs.

FIG. 6 schematically shows another indicative diagram illustrating the signal transmission process according to the embodiment in FIG. 4, when a second stage abnormality occurs.

FIG. 7 shows a structural diagram schematically illustrating a battery management system according to FIG. 4, when the battery detecting and managing circuit further comprises a micro processor and uses firmware operations of the micro processor to disable the power conditioning device.

FIG. 8 shows a structural diagram schematically illustrating a battery management system according to FIG. 4, when the power conditioning device further comprises an emergency stop and uses hardware configuration of the emergency stop to disable the power conditioning device.

### DESCRIPTION OF THE PREFERRED EMBODIMENTS

Reference will now be made in detail to embodiments illustrated in the accompanying drawings. Wherever possible, the same reference numbers will be used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

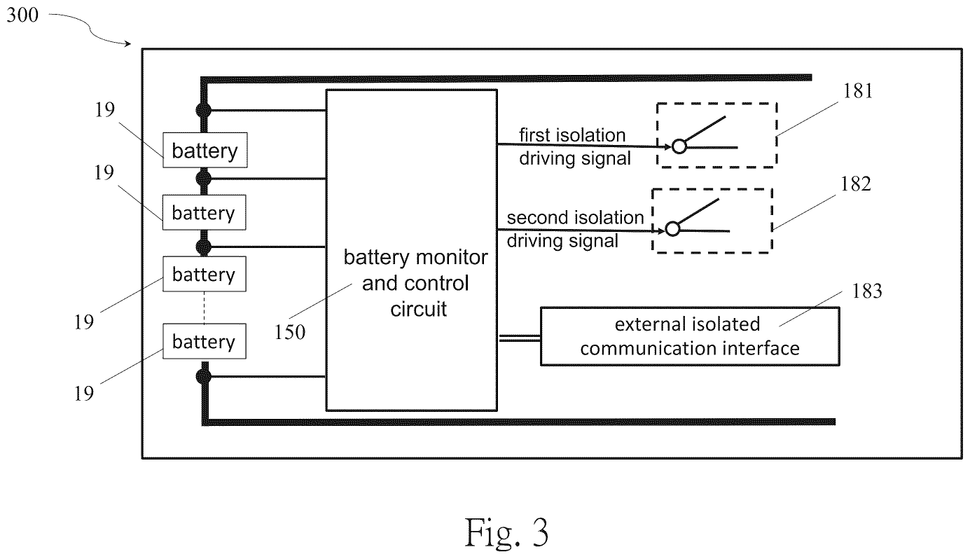

In the following descriptions, a battery monitoring and protection module is to be provided first. Please refer to FIG. 3, which shows a structural diagram schematically illustrating a battery monitoring and protection module in accordance with one embodiment of the present invention. As illustrated in the disclosed embodiment in FIG. 3, the proposed battery monitoring and protection module 300 comprises a battery monitor and control circuit 150, a first stage notification switch 181, a second stage notification switch 182 and an external isolated communication interface 183, such that by employing the proposed circuit configurations in the present invention, the disclosed battery monitoring and protection module 300 is applicable to monitoring and protecting a status of at least one battery 19.

In detailed configurations of the present invention, each battery 19 is electrically coupled to an input terminal of the battery monitor and control circuit 150. The first stage notification switch 181 is electrically coupled to a first output terminal of the battery monitor and control circuit 150, and the second stage notification switch 182 is electrically coupled to a second output terminal of the battery monitor and control circuit 150. According to the embodiment of the present invention, a first isolation driving signal is provided between the battery monitor and control circuit 150 and the first stage notification switch 181, such that the battery monitor and control circuit 150 controls the first stage notification switch 181 through the first isolation driving signal. A second isolation driving signal is provided between the battery monitor and control circuit 150 and the second stage notification switch 182, such that the battery monitor and control circuit 150 controls the second stage notification switch 182 through the second isolation driving signal. On the other hand, the external isolated communication interface 183 is electrically coupled to a third output terminal of the battery monitor and control circuit 150, and the external isolated communication interface 183 is different from communication interfaces coupled to the first stage notification switch 181 and to the second stage notification switch 182.

According to the technical solution provided in the present invention, the battery monitor and control circuit 150 is operable to detect the status of the at least one battery 19 and accordingly controls the first stage notification switch 181 and the second stage notification switch 182 based on the detection result, for the purpose of protecting the at least one battery 19.

For instance, according to the embodiment of the present invention, the status of the at least one battery 19 includes “a normal status”, “an abnormal status” and “an approaching-abnormal status” of the at least one battery 19 regarding an operating voltage, an operating current and an operating temperature of the at least one battery 19.

In the following descriptions, the Applicant of the present invention takes a lithium battery as an example for explanation. Generally speaking, the abnormal status of a lithium battery may include the following five types, when the operating voltage is too high, the operating voltage is too low, the operating temperature is too high, the operating temperature is too low, and the operating current is too high. And therefore, taking a single lithium battery as the battery 19 of the present invention as an example, the “normal status” of the battery 19 can be set as: the operating voltage is less than 3.6 volts (Voltage, V), the “approaching-abnormal status” can be set as: the operating voltage is greater than 3.6V, and the “abnormal status” can be set as: the operating voltage is greater than 3.65V.

Similarly, in another embodiment of the present invention, the “normal status” of the battery 19 can be set as: the operating voltage should be greater than 2.55 volts (Voltage, V), the “approaching-abnormal status” can be set as: the operating voltage is less than 2.55V, and the “abnormal status” can be set as: the operating voltage is less than 2.5V.

In addition, regarding the operating temperature of the battery 19, the “normal status” of the battery 19 can be set as: the operating temperature should be less than 55 °C (Celsius degree), the “approaching-abnormal status” can be set as: the operating temperature is greater than 55 °C, and the “abnormal status” can be set as: the operating temperature is greater than 60 °C. On the contrary, the “normal status” of the battery 19 can be alternatively set as: the operating temperature should be greater than 5 °C (Celsius degree), the “approaching-abnormal status” can be set as: the operating temperature is less than 5 °C, and the “abnormal status” can be set as: the operating temperature is less than 0 °C

And yet, regarding the operating current of the battery 19, the “normal status” of the battery 19 can be set as: the operating current should be less than 0.95 ampere (A), the “approaching-abnormal status” can be set as: the operating current is greater than 0.95A, and the “abnormal status” can be set as: the operating current is greater than 1.0A.

As a result, when the battery monitor and control circuit 150 of the battery monitoring and protection module 300 detects the status of the at least one battery 19 is normal, the battery monitor and control circuit 150 controls each of the first stage notification switch 181 and the second stage notification switch 182 to form a short circuit.

In addition, when the battery monitor and control circuit 150 of the battery monitoring and protection module 300 detects the status of the at least one battery 19 is approaching abnormal, the battery monitor and control circuit 150 controls the first stage notification switch 181 to form an open circuit, and the second stage notification switch 182 is remained to form a short circuit.

And yet, when the battery monitor and control circuit 150 of the battery monitoring and protection module 300 detects the status of the at least one battery 19 is abnormal, then the battery monitor and control circuit 150 controls each of the first stage notification switch 181 and the second stage notification switch 182 to form an open circuit.

In consideration of the actual circuit configurations, according to a feasible embodiment of the present invention, in order to effectively enable the first stage notification switch 181 and the second stage notification switch 182 to form an open circuit or a short circuit, the first stage notification switch 181, for instance, can be implemented by using a relay or an optical coupler switch. Similarly, the second stage notification switch 182 can be implemented by using a relay or an optical coupler switch as well. However, the present invention is certainly not limited thereto. For people who are skilled in the art and having ordinary knowledge in the field, modifications without departing from the spirit of the present invention are permitted. However, within the scope of its equality, such modifications should still fall into the scope and claims of the present invention.

As a result, as can be seen in FIG. 3 of the present invention, when there are a plurality of the batteries 19 which are connected in cascade in the system, and the battery monitor and control circuit 150 is electrically coupled to the plurality of the batteries 19 which are connected in cascade, as long as the status of the at least one battery 19 has changed, the battery monitor and control circuit 150 is able to detect the changed status of the at least one battery 19. And accordingly, the battery monitor and control circuit 150 is operable to protect the at least one battery 19 by controlling the first stage notification switch 181 and the second stage notification 182. For instance, the battery monitor and control circuit 150 controls the first stage notification switch 181 and the second stage notification 182 to form the above disclosed open circuit, or short circuit.

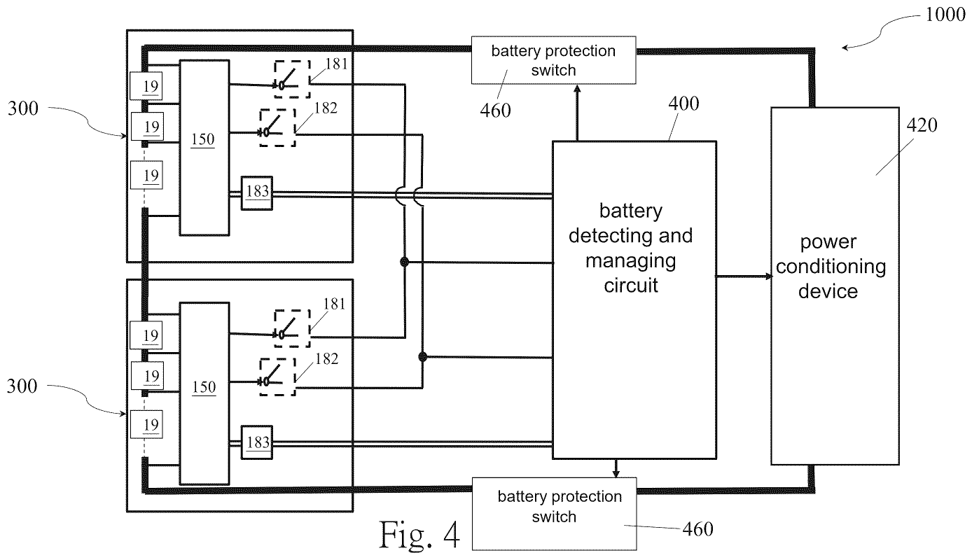

Furthermore, please refer to FIG. 4, which shows a structural diagram schematically illustrating a battery management system 1000 formed by using the above mentioned battery monitoring and protection module 300 in accordance with the embodiment of the present invention. As illustrated in the disclosed embodiment in FIG. 4, the proposed battery management system 1000 includes a plurality of the battery monitoring and protection modules 300 as mentioned previously, a battery detecting and managing circuit 400, a power conditioning device 420 and at least one battery protection switch 460. According to the embodiment of the present invention, the plurality of the battery monitoring and protection modules 300 are electrically connected in series.

As shown in FIG. 4, the first stage notification switch 181 of each of the battery monitoring and protection modules 300 is serially connected. Similarly, the second stage notification switch 182 of each of the battery monitoring and protection modules 300 is serially connected as well. The battery detecting and managing circuit 400 is electrically connected to the first stage notification switch 181 of each of the battery monitoring and protection modules 300, and also connected to the second stage notification switch 182 of each of the battery monitoring and protection modules 300. In addition, the external isolated communication interface 183 of each of the battery monitoring and protection modules 300 is electrically connected to the battery detecting and managing circuit 400.

Based on such circuit configurations, when any one of the battery monitoring and protection modules 300 has a first stage abnormality, the first stage notification switch 181 of the battery monitoring and protection module 300 forms an open circuit, such that the entire serially connected first stage notification switches 181 are disconnected. Under such a condition, when the battery detecting and managing circuit 400 detects the open circuit formed by the entire serially connected first stage notification switches 181, the battery detecting and managing circuit 400 is operable to disable the power conditioning device 420 in order to pause and observe the at least one battery.

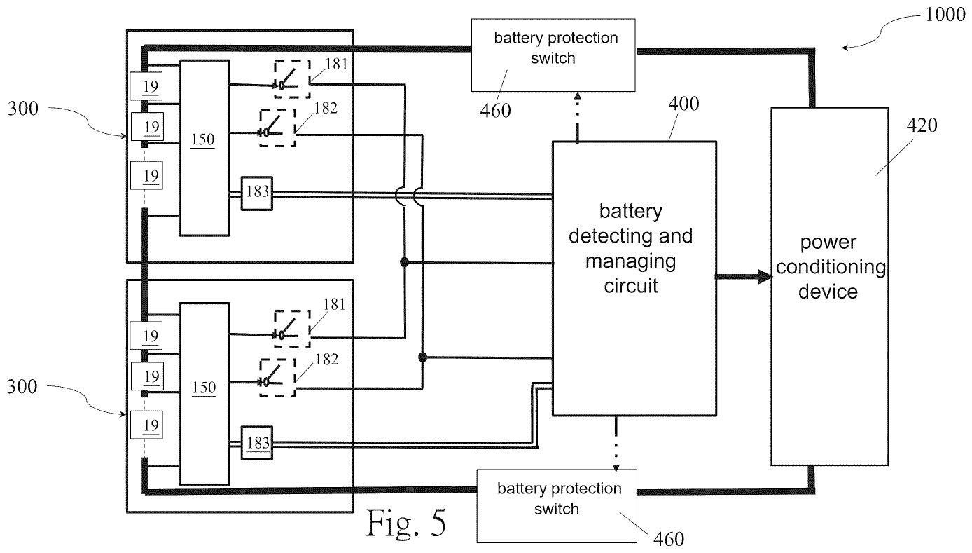

In other words, according to the disclosed embodiment of the present invention, when the proposed battery detecting and managing circuit 400 detects the first stage notification switch 181 of any of the battery monitoring and protection modules 300 forms an open circuit, the battery detecting and managing circuit 400 is able to disable the power conditioning device 420 first, so as to pause and observe the at least one battery 19. Please refer to FIG. 5, which schematically shows an indicative diagram illustrating the signal transmission process according to the embodiment in FIG. 4, when a first stage abnormality occurs. As illustrated by the thicker solid line in FIG. 5, it can be seen that when the first stage abnormality occurs, the power conditioning device 420 is disabled first, such that the battery 19 is paused and observed first to activate a first stage protection of the battery 19.

And furthermore, when any one of the battery monitoring and protection modules 300 in the battery management system 1000 has a second stage abnormality, the second stage notification switch 182 of the battery monitoring and protection module 300 forms an open circuit, such that the entire serially connected second stage notification switches 182 are disconnected. Under such a condition, when the battery detecting and managing circuit 400 detects the open circuit formed by the entire serially connected second stage notification switches 182, the battery detecting and managing circuit 400 is operable to control the at least one battery protection switch 460 to be open so as to cut the current flowing through the battery in order to stop and protect the battery.

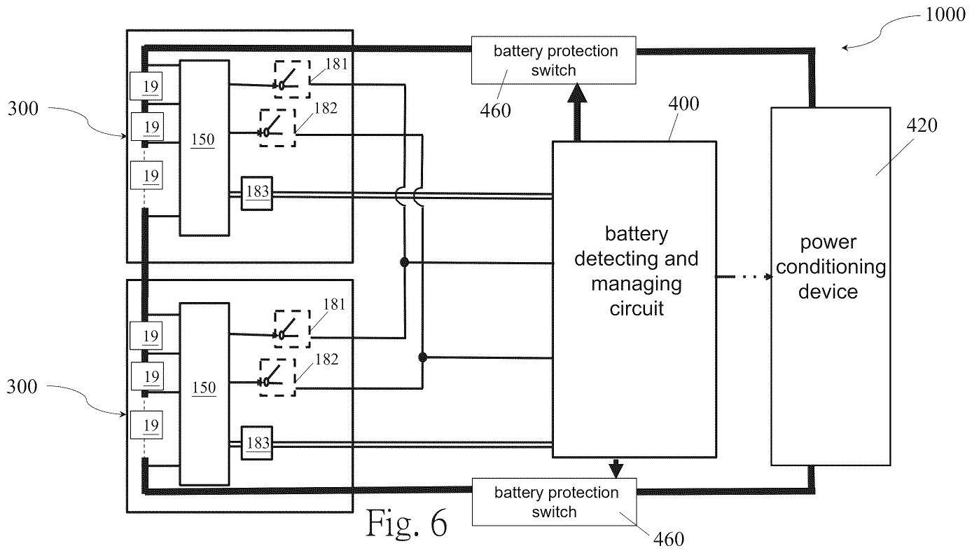

In other words, according to the disclosed embodiment of the present invention, when the proposed battery detecting and managing circuit 400 detects the second stage notification switch 182 of any of the battery monitoring and protection modules 300 forms an open circuit, under such a condition, the battery detecting and managing circuit 400 is able to control the at least one battery protection switch 460 to be open so as to cut a current flowing through the battery 19 so as to stop and protect the battery 19. Please refer to FIG. 6, which schematically shows an indicative diagram illustrating the signal transmission process according to the embodiment in FIG. 4, when a second stage abnormality occurs. As illustrated by the thicker solid line in FIG. 6, it can be seen that when the second stage abnormality occurs in the battery management system 1000, the battery protection switch 460 is accordingly disconnected, such that the current is cut, and the battery 19 is stopped and under protection.

To sum up, in view of the disclosed technical contents of the present invention, by employing the proposed the battery monitoring and protection module 300 and the battery management system 1000 formed by using the battery monitoring and protection module 300, the present invention achieves in notifying the power conditioning device 420 immediately and disconnecting the battery protection switch 460 to cut off the current path. Rapid protection effect without communication and data processing can be accomplished. For instance, by adopting the present invention, the protection activation time can be effectively shortened to millisecond (ms) level. In addition, the communication data processing time can be shortened to once per second, which significantly saves the huge amount of power consumed by communication processing in the prior art and thus makes a less burden of data processing and communication time. Even if communication packets may be sometimes lost in the system, there is still enough time to confirm again, and the battery can still be under well and in-time protection by using the present invention.

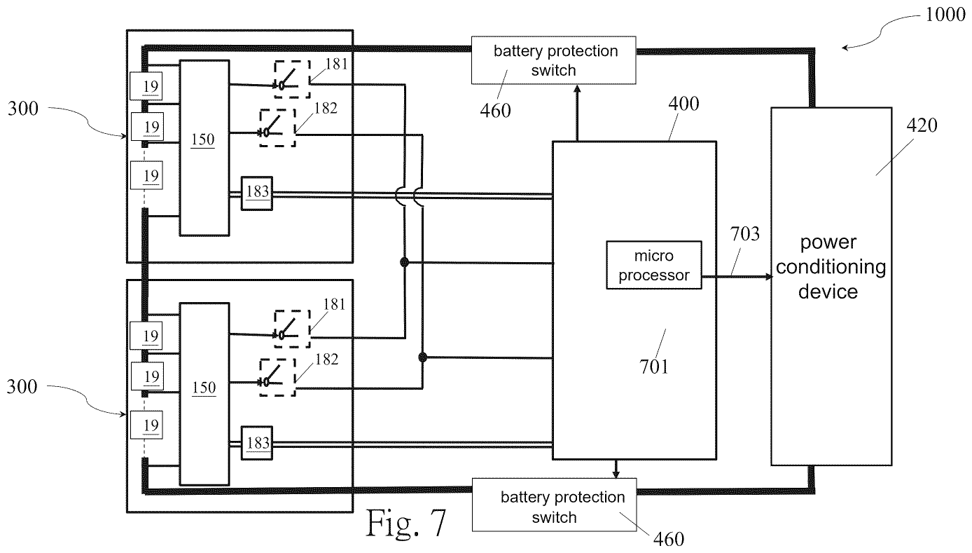

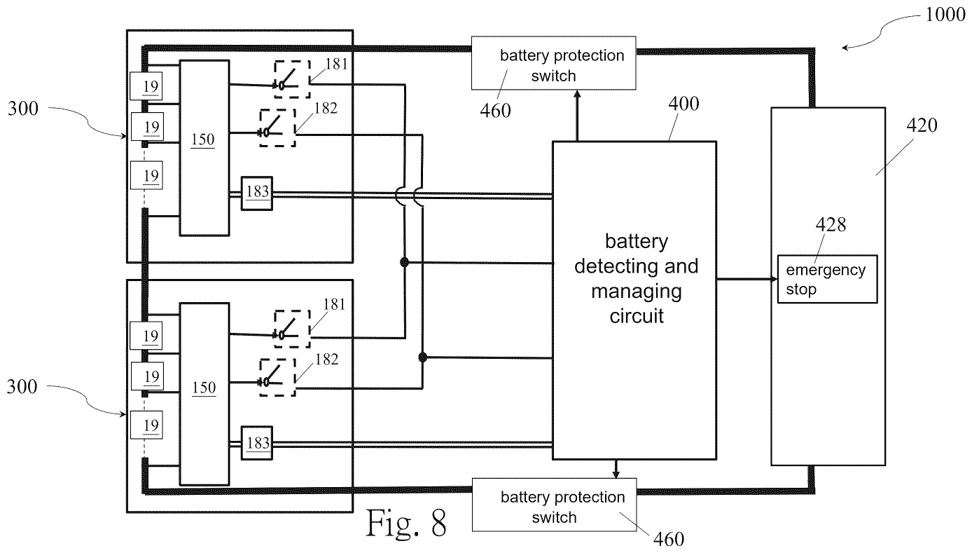

And yet, in another aspect, in the following paragraphs, the Applicant of the present invention further provides two feasible embodiments as shown in FIG. 7 and FIG. 8, for implementing the above mentioned first stage protection when the power conditioning device 420 can be disabled so the battery 19 is paused and observed.

As illustrated in one feasible embodiment in FIG. 7, it is applicable that the battery detecting and managing circuit 400 further comprises a micro processor 701, such that by employing the firmware operations of the micro processor 701, the battery detecting and managing circuit 400 is able to use the micro processor 701 to disable the power conditioning device 420 connected thereto, so as to pause and observe the battery. According to such an embodiment, an RS485 communication interface or an ethernet interface can be provided between the micro processor 701 and the power conditioning device 420 as an signal transmission interface 703 there in between, such that the micro processor 701 is operable to control the power conditioning device 420 via the RS485 communication interface or the ethernet interface.

On the other hand, FIG. 8 discloses another feasible embodiment to notify the power conditioning device 420 so as to activate the previously disclosed first stage protection of the present invention. As can be seen in FIG. 8, then it may also be applicable to dispose an emergency stop 428 on the power conditioning device 420, such that the power conditioning device 420 further comprises the emergency stop 428 thereon. As a result, by employing such hardware configurations, the battery detecting and managing circuit 400 may also disable and stop the power conditioning device 420 by controlling and activating the emergency stop 428, so that the first stage protection of the present invention can be made.

As such, based on the disclosed technical contents of the present invention, it is obvious that the present invention provides a battery monitoring and protection module for high voltage battery system. It not only improves the communication mode of the existing technologies, but also proposes a faster and more efficient method to start an immediate protection for batteries at the first time.

Apart from the above, the present invention also proposes a battery management system formed by using the battery monitoring and protection modules. In addition to the battery protection effect, improvements regarding battery status communications are made as well. In the present invention, it is not necessary to use extremely fast and instant communication mode, as in the conventional related arts. The present invention offers the signals to communicate by using a lower communication rate. As such, not only power consumption is reduced, but also no malfunctions will be caused. As a result, it is believed that the present invention in characterized by having better industrial compatibility and wider application range than the current existing technology and therefore is extremely innovative and practical. In addition, based on the present invention, it can not only be effectively applied to lithium batteries, but also can be widely applied to other battery materials. Those skilled in the art are able to make equivalent modifications and variations based on the actual product specifications without departing from the spirits of the invention. Nevertheless, such modified embodiments should still fall within the claim scope of the present invention. Therefore, as a matter of fact, the Applicants assert that the present invention is instinct, effective and highly competitive for the incoming technologies, industries and researches developed in the future. And since the technical features, means and effects achieved by the present invention are significantly different from the current solutions and can not be accomplished easily by those who are familiar with the industry, it is thus believed that the present invention is indeed characterized by patentability and shall be patentable soon in a near future.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A battery monitoring and protection module, applicable to monitoring and protecting a status of at least one battery, the battery monitoring and protection module comprising:
a battery monitor and control circuit, wherein the at least one battery is electrically coupled to an input terminal of the battery monitor and control circuit;
a first stage notification switch, which is electrically coupled to a first output terminal of the battery monitor and control circuit; and
a second stage notification switch, which is electrically coupled to a second output terminal of the battery monitor and control circuit, wherein the battery monitor and control circuit detects the status of the at least one battery and accordingly controls the first stage notification switch and the second stage notification switch for protecting the at least one battery.

2. The battery monitoring and protection module according to claim 1, wherein when the battery monitor and control circuit detects the status of the at least one battery is normal, each of the first stage notification switch and the second stage notification switch forms a short circuit.

3. The battery monitoring and protection module according to claim 1, wherein when the battery monitor and control circuit detects the status of the at least one battery is approaching abnormal, the battery monitor and control circuit controls the first stage notification switch to form an open circuit, and the second stage notification switch to form a short circuit.

4. The battery monitoring and protection module according to claim 1, wherein when the battery monitor and control circuit detects the status of the at least one battery is abnormal, the battery monitor and control circuit controls each of the first stage notification switch and the second stage notification switch to form an open circuit.

5. The battery monitoring and protection module according to claim 1, wherein the first stage notification switch is a relay or an optical coupler switch.

6. The battery monitoring and protection module according to claim 1, wherein the second stage notification switch is a relay or an optical coupler switch.

7. The battery monitoring and protection module according to claim 1, wherein the battery monitor and control circuit controls the first stage notification switch through a first isolation driving signal.

8. The battery monitoring and protection module according to claim 7, wherein the battery monitor and control circuit controls the second stage notification switch through a second isolation driving signal.

9. The battery monitoring and protection module according to claim 8, wherein the battery monitor and control circuit further comprises a third output terminal which is electrically coupled to an external isolated communication interface, and the external isolated communication interface is different from communication interfaces coupled to the first stage notification switch and to the second stage notification switch.

10. The battery monitoring and protection module according to claim 1, wherein when the battery monitor and control circuit is electrically coupled to a plurality of the batteries which are connected in cascade, and detects the status of the at least one battery has changed, the battery monitor and control circuit is operable to protect the at least one battery by controlling the first stage notification switch and the second stage notification.

11. The battery monitoring and protection module according to claim 1, wherein the status of the at least one battery includes a normal status, an abnormal status and an approaching-abnormal status of the at least one battery regarding an operating voltage, an operating current and an operating temperature of the at least one battery.

12. A battery management system formed by using the battery monitoring and protection module according to claim 1, comprising:
a plurality of the battery monitoring and protection modules which are connected in series;
a battery detecting and managing circuit, which is electrically connected to the first stage notification switch of each of the battery monitoring and protection modules; and
a power conditioning device, which is electrically connected to the battery detecting and managing circuit, wherein when the battery detecting and managing circuit detects the first stage notification switch of any of the battery monitoring and protection modules forms an open circuit, the battery detecting and managing circuit disables the power conditioning device to pause and observe the at least one battery.

13. The battery management system formed by using the battery monitoring and protection module according to claim 12, wherein the first stage notification switch of each of the battery monitoring and protection modules is serially connected.

14. The battery management system formed by using the battery monitoring and protection module according to claim 12, further comprising at least one battery protection switch, which is electrically connected with the battery detecting and managing circuit, wherein the battery detecting and managing circuit is electrically connected to the second stage notification switch of each of the battery monitoring and protection modules, and when the battery detecting and managing circuit detects the second stage notification switch of any of the battery monitoring and protection modules forms the open circuit, the battery detecting and managing circuit controls the at least one battery protection switch to be open so as to cut a current flowing through the at least one battery in order to stop and protect the at least one battery.

15. The battery management system formed by using the battery monitoring and protection module according to claim 14, wherein the second stage notification switch of each of the battery monitoring and protection modules is serially connected.

16. The battery management system formed by using the battery monitoring and protection module according to claim 12, wherein the battery detecting and managing circuit is electrically connected with an external isolated communication interface of each of the battery monitoring and protection modules in common.

17. The battery management system formed by using the battery monitoring and protection module according to claim 12, wherein the battery detecting and managing circuit further comprises a micro processor, such that the battery detecting and managing circuit uses the micro processor to disable the power conditioning device so as to pause and observe the at least one battery.

18. The battery management system formed by using the battery monitoring and protection module according to claim 17, wherein an RS485 communication interface or an ethernet interface is provided between the micro processor and the power conditioning device, such that the micro processor is operable to control the power conditioning device via the RS485 communication interface or the ethernet interface.

19. The battery management system formed by using the battery monitoring and protection module according to claim 12, wherein the power conditioning device further comprises an emergency stop, such that the battery detecting and managing circuit disables the power conditioning device by activating the emergency stop.

20. The battery management system formed by using the battery monitoring and protection module according to claim 12, wherein the status of the at least one battery includes a normal status, an abnormal status and an approaching-abnormal status of the at least one battery regarding an operating voltage, an operating current and an operating temperature of the at least one battery.
